(19) United States
(12) Patent Application Publication
(10) Pub. No.: US 2025/0287694 A1
(43) Pub. Date: Sep. 11, 2025

(54) BACKSIDE ISOLATION PILLAR REMOVAL FOR CAPACITANCE REDUCTION

(71) Applicant: International Business Machines Corporation, Armonk, NY (US)

(72) Inventors: Tsung-Sheng Kang, Ballston Lake, NY (US); Tao Li, Slingerlands, NY (US); Ruilong Xie, Niskayuna, NY (US); Shay Reboh, Guilderland, NY (US)

(21) Appl. No.: 18/596,698

(22) Filed: Mar. 6, 2024

(51) Int. Cl. H01L 27/12; H01L 21/764

(52) U.S. Cl. CPC H10D 86/60; H01L 21/764; H10D 86/021; H10D 86/451

(57) ABSTRACT

A semiconductor device is provided and includes first and second active regions, a shared gate structure disposed across the first and second active regions and including first and second metal gate material in the first and second active regions, respectively, a self-aligned backside dielectric pillar interposed between a first portion of the first metal gate material and a first portion of the second metal gate material and a shared gate plug interposed between a second portion of the first metal gate material and a second portion of the second metal gate material. The self-aligned backside dielectric pillar defines a pinched-off air gap extending across a width-wise portion of the self-aligned backside dielectric pillar and along a height-wise portion of the self-aligned backside dielectric pillar.

### BACKGROUND

The present disclosure generally relates to fabrication methods and resulting structures for semiconductor devices. More specifically, the present disclosure relates backside isolation pillar removal for capacitance reduction for shared and non-shared gates for semiconductor devices.

A transistor is a semiconductor device used to amplify or switch electrical signals and power and is one of the basic building blocks of modern electronics. A field-effect transistor (FET) is a type of transistor that uses an electric field to control the flow of current in a semiconductor. An FET has three terminals: a source, a gate and a drain. FETs control the flow of current by the application of a voltage to the gate, which in turn alters the conductivity between the drain and the source.

### SUMMARY

According to an aspect of the disclosure, a semiconductor device is provided and includes first and second active regions, a shared gate structure disposed across the first and second active regions and including first and second metal gate material in the first and second active regions, respectively, a self-aligned backside dielectric pillar interposed between a first portion of the first metal gate material and a first portion of the second metal gate material and a shared gate plug interposed between a second portion of the first metal gate material and a second portion of the second metal gate material. The self-aligned backside dielectric pillar defines a pinched-off air gap extending across a width-wise portion of the self-aligned backside dielectric pillar and along a height-wise portion of the self-aligned backside dielectric pillar. In additional or alternative embodiments, the pinched-off air gap reduces parasitic capacitance between the first and second metal gate materials.

According to an aspect of the disclosure, a semiconductor device is provided and includes first and second active regions, a non-shared gate structure disposed across the first and second active regions and including first and second metal gate material in the first and second active regions, respectively, and a self-aligned backside dielectric pillar interposed between the first metal gate material and the second metal gate material. The backside dielectric pillar defines a pinched-off air gap extending across a width-wise portion of the self-aligned backside dielectric pillar and along a height-wise portion of the self-aligned backside dielectric pillar. In additional or alternative embodiments, the pinched-off air gap reduces parasitic capacitance between the first and second metal gate materials.

According to an aspect of the disclosure, a semiconductor device fabrication method is provided and includes forming a gate structure across first and second active regions and including first and second metal gate material in the first and second active regions, respectively, and first and second support structures underlying the first and second metal gate material, respectively, removing material from between the first and second metal gate material and from between the first and second support structures to form first and second openings, respectively, executing atomic layer deposition (ALD) to partially fill the first opening with dielectric defining a pinched-off air gap therein and to partially fill the second opening with the dielectric defining a partially pinched-off air gap therein and executing additional ALD to completely fill the partially pinched-off air gap with the dielectric whereby the dielectric forms a self-aligned backside dielectric pillar. In additional or alternative embodiments, the pinched-off air gap reduces parasitic capacitance between the first and second metal gate materials.

Additional technical features and benefits are realized through the techniques of the present disclosure. Embodiments and aspects of the disclosure are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the disclosure are apparent from the following detailed description taken in conjunction with the accompanying drawings in which:

FIG. 1 is a top-down view of a semiconductor device in accordance with one or more embodiments;

FIG. 2A is a side view of the semiconductor device of FIG. 1 in accordance with one or more embodiments;

FIG. 2B is a side view of an enlarged portion of the semiconductor device of FIG. 2A in accordance with one or more embodiments;

FIG. 3A is a side view of the semiconductor device of FIG. 1 in accordance with one or more embodiments;

FIG. 3B is a side view of an enlarged portion of the semiconductor device of FIG. 3A in accordance with one or more embodiments;

FIG. 4 is a flow diagram illustrating a semiconductor device fabrication method in accordance with one or more embodiments;

FIG. 5 is a side view of an initial semiconductor device assembly in accordance with one or more embodiments;

FIG. 6 is a side view of a second semiconductor device assembly in accordance with one or more embodiments;

FIG. 7 is a side view of a third semiconductor device assembly in accordance with one or more embodiments; and

FIG. 8 is a side view of a fourth semiconductor device assembly in accordance with one or more embodiments.

The diagrams depicted herein are illustrative. There can be many variations to the diagram or the operations described therein without departing from the spirit of the disclosure. For instance, the actions can be performed in a differing order or actions can be added, deleted or modified. Also, the term “coupled” and variations thereof describes having a communications path between two elements and does not imply a direct connection between the elements with no intervening elements/connections between them. All of these variations are considered a part of the specification.

In the accompanying figures and following detailed description of the described embodiments, the various elements illustrated in the figures are provided with two or three digit reference numbers. With minor exceptions, the leftmost digit(s) of each reference number correspond to the figure in which its element is first illustrated.

### DETAILED DESCRIPTION

According to an aspect of the disclosure, a semiconductor device is provided and includes first and second active regions, a shared gate structure disposed across the first and second active regions and including first and second metal gate material in the first and second active regions, respectively, a self-aligned backside dielectric pillar interposed between a first portion of the first metal gate material and a first portion of the second metal gate material and a shared gate plug interposed between a second portion of the first metal gate material and a second portion of the second metal gate material. The self-aligned backside dielectric pillar defines a pinched-off air gap extending across a width-wise portion of the self-aligned backside dielectric pillar and along a height-wise portion of the self-aligned backside dielectric pillar. In additional or alternative embodiments, the pinched-off air gap reduces parasitic capacitance between the first and second metal gate materials.

In accordance with additional or alternative embodiments, the shared gate structure includes first and second gate structures in the first and second active regions, the first gate structure includes first nanosheets surrounded by the first metal gate material and the second gate structure includes second nanosheets surrounded by the second metal gate material. The semiconductor device can therefore be provided as a field effect transistor (FET) device.

In accordance with additional or alternative embodiments, the semiconductor device further includes interlayer dielectric (ILD) extending across the first and second gate structures, a back-end-of-line (BEOL) layer disposed on the ILD, a frontside contact extending through the ILD and being electrically connected to the shared gate plug and the BEOL layer and a carrier layer disposed on the BEOL layer. The semiconductor device is therefore complementary-metal-oxide-semiconductor (CMOS) compatible.

In accordance with additional or alternative embodiments, the semiconductor device further includes a backside power rail (BPR) and a backside contact electrically connected to the BPR. The semiconductor device therefore provides for connection with a backside power distribution network (BSPDN).

In accordance with additional or alternative embodiments, the pinched-off air gap is ovular and elongate height-wise and contributes to reduction of parasitic capacitance between the first and second metal gate materials more than in a vertical direction.

In accordance with additional or alternative embodiments, the self-aligned backside dielectric pillar includes an upper pinched-off section delimiting an upper extent of the pinched-off air gap and proximate to the shared gate plug and a lower pinched-off section delimiting a lower extent of the pinched-off air gap and proximate to a lowermost plane of the first and second metal gate materials in the first and second active regions, respectively. The upper and lower pinched-off sections can therefore be formed as a direct result of atomic layer deposition (ALD) processing.

In accordance with additional or alternative embodiments, the side sections of the self-aligned backside dielectric pillar have a minimum width corresponding to a maximum width of the pinched-off air gap and respective widths of the side sections are up to about 20-33% of a total width of the backside dielectric pillar. The pinched-off air gap therefore occupies a significant fraction of the volume of the backside dielectric pillar.

According to an aspect of the disclosure, a semiconductor device is provided and includes first and second active regions, a non-shared gate structure disposed across the first and second active regions and including first and second metal gate material in the first and second active regions, respectively, and a self-aligned backside dielectric pillar interposed between the first metal gate material and the second metal gate material. The backside dielectric pillar defines a pinched-off air gap extending across a width-wise portion of the self-aligned backside dielectric pillar and along a height-wise portion of the self-aligned backside dielectric pillar. In additional or alternative embodiments, the pinched-off air gap reduces parasitic capacitance between the first and second metal gate materials.

In accordance with additional or alternative embodiments, the non-shared gate structure includes first and second gate structures in the first and second active regions, the first gate structure including first nanosheets surrounded by the first metal gate material and the second gate structure including second nanosheets surrounded by the second metal gate material. The semiconductor device can therefore be provided as a field effect transistor (FET) device.

In accordance with additional or alternative embodiments, the semiconductor device further includes interlayer dielectric (ILD) extending across the first and second gate structures, a back-end-of-line (BEOL) layer disposed on the ILD and a carrier layer disposed on the BEOL layer. The semiconductor device is therefore complementary-metal-oxide-semiconductor (CMOS) compatible.

In accordance with additional or alternative embodiments, the semiconductor device further includes a backside power rail (BPR) and a backside contact electrically connected to the BPR. The semiconductor device therefore provides for connection with a backside power distribution network (BSPDN).

In accordance with additional or alternative embodiments, the pinched-off air gap is ovular and elongate height-wise and contributes to reduction of parasitic capacitance between the first and second metal gate materials more than in a vertical direction.

In accordance with additional or alternative embodiments, the self-aligned backside dielectric pillar includes an upper pinched-off section delimiting an upper extent of the pinched-off air gap and proximate an uppermost plane of the first and second metal gate materials in the first and second active regions, respectively, and a lower pinched-off section delimiting a lower extent of the pinched-off air gap and proximate to a lowermost plane of the first and second metal gate materials in the first and second active regions, respectively. The upper and lower pinched-off sections can therefore be formed as a direct result of atomic layer deposition (ALD) processing.

In accordance with additional or alternative embodiments, side sections of the self-aligned backside dielectric pillar have a minimum width corresponding to a maximum width of the pinched-off air gap and respective widths of the side sections are up to about 20-33% of a total width of the backside dielectric pillar. The pinched-off air gap therefore occupies a significant fraction of the volume of the backside dielectric pillar.

According to an aspect of the disclosure, a semiconductor device fabrication method is provided and includes forming a gate structure across first and second active regions and including first and second metal gate material in the first and second active regions, respectively, and first and second support structures underlying the first and second metal gate material, respectively, removing material from between the first and second metal gate material and from between the first and second support structures to form first and second openings, respectively, executing atomic layer deposition (ALD) to partially fill the first opening with dielectric defining a pinched-off air gap therein and to partially fill the second opening with the dielectric defining a partially pinched-off air gap therein and executing additional ALD to completely fill the partially pinched-off air gap with the dielectric whereby the dielectric forms a self-aligned backside dielectric pillar. In additional or alternative embodiments, the pinched-off air gap reduces parasitic capacitance between the first and second metal gate materials.

In accordance with additional or alternative embodiments, the gate structure is one of a shared gate structure and a non-shared gate structure with the pinched-ff air gap being useful in both cases though somewhat taller in the non-shared case.

In accordance with additional or alternative embodiments, the pinched-off air gap is ovular and elongate height-wise and contributes to reduction of parasitic capacitance between the first and second metal gate materials more than in a vertical direction.

In accordance with additional or alternative embodiments, the executing of the ALD includes executing the ALD to form an upper pinched-off section delimiting an upper extent of the pinched-off air gap and proximate an uppermost plane of the first and second gate metal materials in the first and second active regions, respectively, and executing the ALD to form a lower pinched-off section delimiting a lower extent of the pinched-off air gap and proximate to a lowermost plane of the first and second gate metal materials in the first and second active regions, respectively. The upper and lower pinched-off sections can be formed as a direct result of atomic layer deposition (ALD) processing.

In accordance with additional or alternative embodiments, the executing of the ALD includes executing the ALD such that side sections of the self-aligned backside dielectric pillar have a minimum width corresponding to a maximum width of the pinched-off air gap and the executing of the ALD includes executing the ALD such that respective widths of the side sections are up to about 20-33% of a total width of the backside dielectric pillar. The pinched-off air gap therefore occupies a significant fraction of the volume of the backside dielectric pillar.

In accordance with additional or alternative embodiments, the semiconductor device fabrication method further includes completing complementary-metal-oxide-semiconductor (CMOS) operations and completing backside power rail (BPR) formations. The semiconductor device is therefore complementary-metal-oxide-semiconductor (CMOS) compatible and provides for connection with a backside power distribution network (BSPDN).

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the disclosure, certain semiconductor device structures are characterized as having a shared metal gate with a backside dielectric pillar for isolation between neighboring gate structures. In these or other similar cases, there can be a parasitic capacitance between metal gate materials of the neighboring gate structures across the backside dielectric pillar when the metal gate materials of the neighboring gate structures are relatively close to one another. This can be due to the incidence of defects at interfaces between the metal gate materials of the neighboring gate structures and the backside dielectric pillar.

An airgap formed in the backside dielectric pillar between the metal gate material of the neighboring gate structures can reduce parasitic capacitance issues due to the fact that dielectric materials, such as air in air gaps, tend not to dissipate charge. It is often difficult, however, to form airgaps in the backside dielectric pillar between metal gate material of the neighboring gate structures.

Turning now to an overview of the aspects of the disclosure, one or more embodiments of the disclosure address the above-described shortcomings of the prior art by providing a semiconductor device with an airgap, which is formed within a backside dielectric pillar between metal gate materials of neighboring gate structures, and S/D self-aligned dielectric isolation in order to reduce parasitic capacitance. In addition, processes are provided to enable backside self-aligned shallow trench isolation (STI) cut and dielectric fill operations for the airgap formation within dielectric isolation provided by the backside dielectric pillar.

The above-described aspects of the disclosure address the shortcomings of the prior art by providing for a semiconductor device that includes first and second active regions, a shared gate structure disposed across the first and second active regions and including first and second metal gate material in the first and second active regions, respectively, a self-aligned backside dielectric pillar interposed between a first portion of the first metal gate material and a first portion of the second metal gate material and a shared gate plug interposed between a second portion of the first metal gate material and a second portion of the second metal gate material. The self-aligned backside dielectric pillar defines a pinched-off air gap extending across a width-wise portion of the self-aligned backside dielectric pillar and along a height-wise portion of the self-aligned backside dielectric pillar.

In addition, the above-described aspects of the disclosure address the shortcomings of the prior art by providing for a semiconductor device that includes first and second active regions, a non-shared gate structure disposed across the first and second active regions and including first and second metal gate material in the first and second active regions, respectively, and a self-aligned backside dielectric pillar interposed between the first metal gate material and the second metal gate material. The backside dielectric pillar defines a pinched-off air gap extending across a width-wise portion of the self-aligned backside dielectric pillar and along a height-wise portion of the self-aligned backside dielectric pillar.

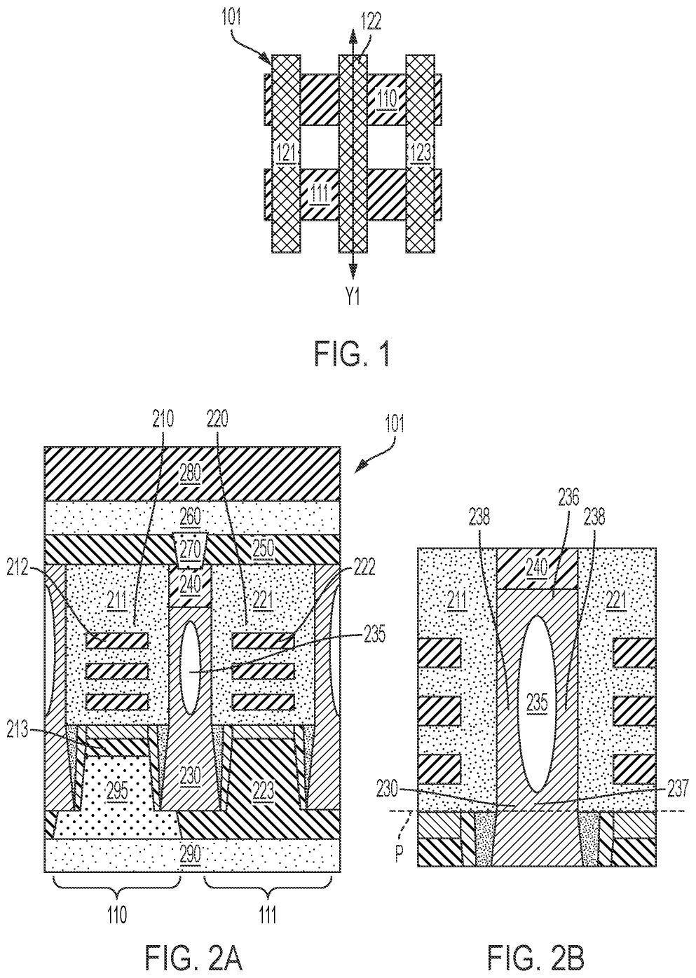

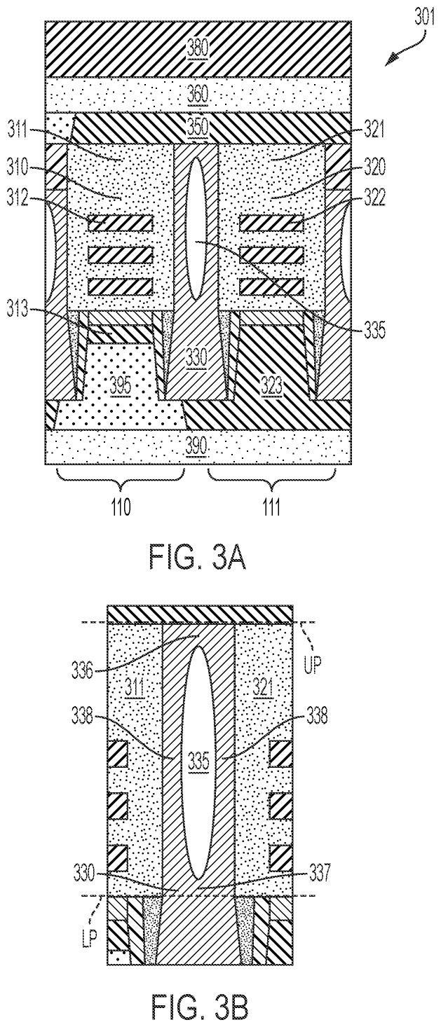

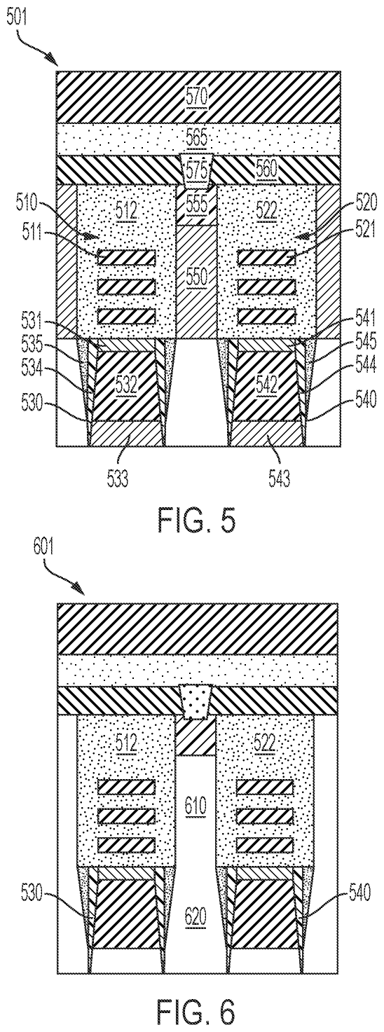

Turning now to a more detailed description of aspects of the present disclosure, FIG. 1 depicts a top-down view of a semiconductor device 101. FIGS. 2A and 2B and FIGS. 3A and 3B are side views of the semiconductor device 101 each in accordance with one or more embodiments and each taken from a perspective defined by cross-sectional view Y1 of FIG. 1. FIGS. 5-8 are side views of the semiconductor device 101 in various stages of assembly in accordance with one or more alternative embodiments and are each taken from the perspective defined by cross-sectional view Y1 of FIG. 1.

As shown in FIG. 1, the semiconductor device 101 includes first and second active regions 110 and 111 and first gate region 121, second gate region 122 and third gate region 123. The first gate region 121 is disposed across the first and second active regions 110 and 111, the second gate region 122 is disposed across the first and second active regions 110 and 111 and the third gate region 123 is disposed across the first and second active regions 110 and 111.

As shown in FIGS. 1, 2A and 2B (FIGS. 2A and 2B relate to the second gate region 122 of FIG. 1) and in accordance with one or more embodiments, the second gate region 122 of the semiconductor device 101 can be characterized as a shared gate structure 201 that is disposed across the first and second active regions 110 and 111. The shared gate structure 201 includes a first gate structure 210 in the first active region 110 and a second gate structure 220 in the second active region 111. The first gate structure 210 in the first active region 110 includes first metal gate material 211, first nanosheets 212 surrounded by the first metal gate material 211 and a first gate support structure 213 underlying the first metal gate material 211. The second gate structure 220 in the second active region 111 includes second metal gate material 221, second nanosheets 222 surrounded by the second metal gate material 221 and a second gate support structure 223 underlying the second metal gate material 221.

The semiconductor device 101 further includes a self-aligned backside dielectric pillar 230, which is interposed between a first (i.e., lower) portion of the first metal gate material 211 and a first (i.e., lower) portion of the second metal gate material 221 and between the first and second gate support structures 213 and 223, and a shared gate plug 240. The shared gate plug 240 is disposed on the self-aligned backside dielectric pillar 230 and is interposed between a second (i.e., upper) portion of the first metal gate material 211 and a second (i.e., upper) portion of the second metal gate material 221. In addition, the semiconductor device 101 also includes interlayer dielectric (ILD) 250 extending across the first and second gate structures 210 and 220, a back-end-of-line (BEOL) layer 260 disposed on the ILD 250, a frontside contact 270 extending through the ILD 250, a carrier layer 280, a backside power rail (BPR) 290 and a backside contact 295. The frontside contact 270 is electrically connected at opposite ends thereof to the shared gate plug 240 and to the BEOL layer 260. The carrier layer 280 is disposed on the BEOL layer 260. The BPR 290 can include or be provided as a backside power delivery network (BSPDN). The backside contact 295 is electrically connected at opposite ends thereof to the BPR 290 and to source/drain (S/D) epitaxy associated with one of the first and second gate structures 210 and 220.

The self-aligned backside dielectric pillar 230 is formed to define a pinched-off air gap 235. The pinched-off air gap 235 extends in a width dimension across a width-wise portion of the self-aligned backside dielectric pillar 230 and extends in a height dimension along a height-wise portion of the self-aligned backside dielectric pillar 230. In accordance with one or more embodiments, the pinched-off air gap 235 can be ovular and elongate height-wise (i.e., longer in the height dimension than the width dimension).

In order to form the pinched-off air gap 235, the self-aligned backside dielectric pillar 230 includes an upper pinched-off section 236 and a lower pinched-off section 237. The upper pinched-off section 236 delimits an upper extent of the pinched-off air gap 235 and is disposed proximate to the shared gate plug 240. The lower pinched-off section 237 delimits a lower extent of the pinched-off air gap 235 and is disposed proximate to a lowermost plane P of the first and second gate materials 211 and 221 in the first and second active regions 110 and 111, respectively. The self-aligned backside dielectric pillar 230 also includes side sections 238. The side sections 238 are curved and form sidewalls of the pinched-off air gap 235. The side sections 238 can have a height-wise location of minimum width that corresponds to a height-wise location of maximum width of the pinched-off air gap 235. Also, respective widths of the side sections 238 may be up to about 20-33% of a total width of the backside dielectric pillar 230 (i.e., the side sections 238 can be about 2 nm wide).

With the self-aligned backside dielectric pillar 230 being formed to define the pinched-off air gap 235, the pinched-off air gap 235 provides for a reduced parasitic capacitance of the semiconductor device 101. That is, even where there may be defects in the interfaces between the first and second metal gate materials 211 and 221 with the self-aligned backside dielectric pillar 230, the pinched-off air gap 235 will tend not to dissipate stored charges. An overall performance of the semiconductor device 101 will be improved thereby.

It is to be understood that respective heights of the upper pinched-off section 236 and the lower pinched-off section 237 are controllable in some cases. For example, in an event the semiconductor device 101 exhibits some parasitic capacitance along the self-aligned backside dielectric pillar 230 in the height-wise dimension, the respective heights of the upper pinched-off section 236 and the lower pinched-off section 237 can be decreased so as to correspondingly increase the height of the pinched-off air gap 235.

As shown in FIGS. 1, 3A and 3B (FIGS. 3A and 3B relate to the second gate region 122 of FIG. 1) and in accordance with one or more embodiments, the second gate region 122 of the semiconductor device 101 can be characterized as a non-shared gate structure 301 that is disposed across the first and second active regions 110 and 111. The non-shared gate structure 301 includes a first gate structure 310 in the first active region 110 and a second gate structure 320 in the second active region 111. The first gate structure 310 in the first active region 110 includes first metal gate material 311, first nanosheets 312 surrounded by the first metal gate material 311 and a first gate support structure 313 (which will be described further below) underlying the first metal gate material 311. The second gate structure 320 in the second active region 111 includes second metal gate material 321, second nanosheets 322 surrounded by the second metal gate material 321 and a second gate support structure 323 (which will be described further below) underlying the second metal gate material 321.

The semiconductor device 101 further includes a self-aligned backside dielectric pillar 330, which is interposed between the first metal gate material 311 and the second metal gate material 321 and between the first and second gate support structures 313 and 323. In addition, the semiconductor device 101 also includes interlayer dielectric (ILD) 350 extending across the first and second gate structures 310 and 320, a back-end-of-line (BEOL) layer 360 disposed on the ILD 350, a carrier layer 380, a backside power rail (BPR) 390 and a backside contact 395. The carrier layer 380 is disposed on the BEOL layer 360. The BPR 390 can include or be provided as a backside power delivery network (BSPDN). The backside contact 395 is electrically connected at opposite ends thereof to the BPR 390 and to S/D epitaxy associated with one of the first and second gate structures 310 and 320.

The self-aligned backside dielectric pillar 330 is formed to define a pinched-off air gap 335. The pinched-off air gap 335 extends in a width dimension across a width-wise portion of the self-aligned backside dielectric pillar 330 and extends in a height dimension along a height-wise portion of the self-aligned backside dielectric pillar 330. In accordance with one or more embodiments, the pinched-off air gap 335 can be ovular and elongate height-wise (i.e., longer in the height dimension than the width dimension).

In order to form the pinched-off air gap 335, the self-aligned backside dielectric pillar 330 includes an upper pinched-off section 336 and a lower pinched-off section 337. The upper pinched-off section 336 delimits an upper extent of the pinched-off air gap 335 and is disposed proximate to an uppermost plane UP of the first and second gate materials 311 and 321 in the first and second active regions 110 and 111, respectively. The lower pinched-off section 337 delimits a lower extent of the pinched-off air gap 335 and is disposed proximate to a lowermost plane LP of the first and second gate materials 311 and 321 in the first and second active regions 110 and 111, respectively. The self-aligned backside dielectric pillar 330 also includes side sections 338. The side sections 338 are curved and form sidewalls of the pinched-off air gap 335. The side sections 338 can have a height-wise location of minimum width that corresponds to a height-wise location of maximum width of the pinched-off air gap 335. Also, respective widths of the side sections 338 may be up to about 20-33% of a total width of the backside dielectric pillar 330 (i.e., the side sections 338 can be about 2 nm wide).

With the self-aligned backside dielectric pillar 330 being formed to define the pinched-off air gap 335, the pinched-off air gap 335 provides for a reduced parasitic capacitance of the semiconductor device 101. That is, even where there may be defects in the interfaces between the first and second metal gate materials 311 and 321 with the self-aligned backside dielectric pillar 330, the pinched-off air gap 335 will tend not to dissipate stored charges. An overall performance of the semiconductor device 101 will be improved thereby.

It is to be understood that respective heights of the upper pinched-off section 336 and the lower pinched-off section 337 are controllable in some cases. For example, in an event the semiconductor device 101 exhibits some parasitic capacitance along the self-aligned backside dielectric pillar 330 in the height-wise dimension, the respective heights of the upper pinched-off section 336 and the lower pinched-off section 337 can be decreased so as to correspondingly increase the height of the pinched-off air gap 335.

It is to be understood that, in general, a height of the pinched-off airgap 335 in the non-shared gate structure 301 will be greater than a height of the pinched-off airgap 235 in the shared gate structure 201.

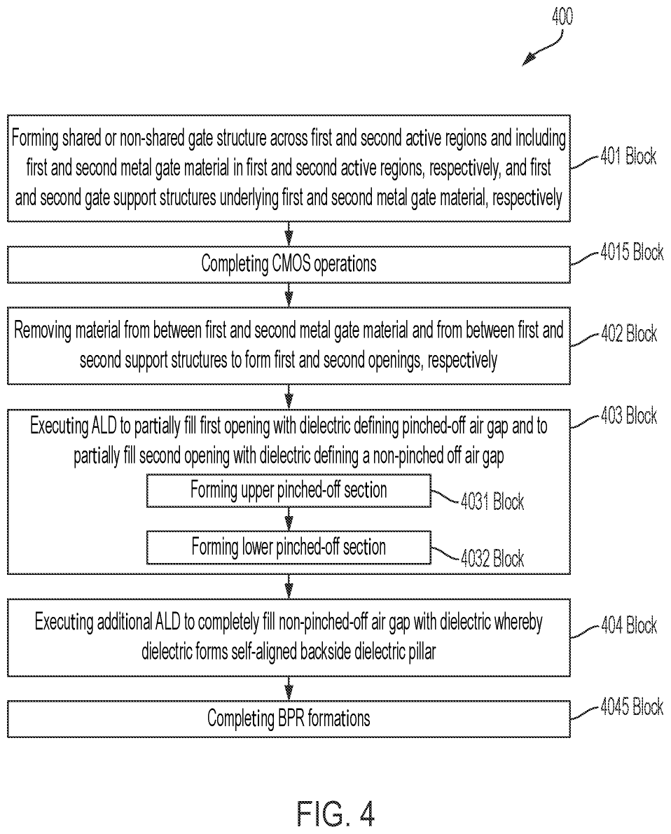

With reference to FIG. 4, a semiconductor device fabrication method 400 is provided to form the semiconductor device 101 of FIG. 1 and FIGS. 2A and 2B and/or the semiconductor device 101 of FIG. 1 and FIGS. 3A and 3B. As shown in FIG. 4, the semiconductor device fabrication method 400 includes forming a shared or non-shared gate structure across first and second active regions and including first and second metal gate material in the first and second active regions, respectively, and first and second gate support structures underlying the first and second metal gate material, respectively (block 401), removing material from between the first and second metal gate material and from between the first and second support structures to form first and second openings, respectively (block 402) executing atomic layer deposition (ALD) to partially fill the first opening with dielectric defining a pinched-off air gap therein, which is ovular and elongate height-wise, and to partially fill the second opening with the dielectric defining a partially pinched-off air gap therein (block 403) and executing additional ALD to completely fill the partially pinched-off air gap with the dielectric whereby the dielectric forms a self-aligned backside dielectric pillar (block 404). The semiconductor device fabrication method 400 can further include completing complementary-metal-oxide-semiconductor (CMOS) operations (block 4015) and completing BPR formations (block 4045).

The executing of the ALD of block 403 can include executing the ALD to form an upper pinched-off section delimiting an upper extent of the pinched-off air gap and proximate an uppermost plane of the first and second gate materials in the first and second active regions, respectively (block 4031) and executing the ALD to form a lower pinched-off section delimiting a lower extent of the pinched-off air gap and proximate to a lowermost plane of the first and second gate materials in the first and second active regions, respectively (block 4032). In addition, the executing of the ALD of block 403 can include executing the ALD such that side sections of the self-aligned backside dielectric pillar have a minimum width corresponding to a maximum width of the pinched-off air gap and such that respective widths of the side sections are up to about 20-33% of a total width of the backside dielectric pillar.

With continued reference to FIG. 4 and with additional reference to FIGS. 5-8, certain operations of the semiconductor device fabrication method 400 will now be described.

Prior to formation of the initial semiconductor device assembly 501 of FIG. 5 being formed, a starting substrate is provided with a first layer of a first semiconductor, a second layer of a second semiconductor disposed on the first layer, an epitaxial layer disposed on the second layer, a third semiconductor layer (SiGe55) disposed on the epitaxial layer and interleaved layers of the first and second semiconductor disposed on the third semiconductor layer. At this point, first gate (RX) patterning and ILD formation are executed followed by second RX patterning to form first and second gate regions and removal of the third semiconductor layer. Next, a bottom dielectric (SASI) layer is formed in each of the first and second gate regions from which the third semiconductor layer was removed, ILD is filled into a trench defined between the first and second gate regions and a fin reveal operation is executed to define shallow trench isolation (STI) regions. This is followed by sidewall SiGe spacer formations (by deposition and etching) to define gate extensions and subsequent self-aligned isolation deposition and etch back, hard mask removal and dummy gate formation. At this point, CMOS S/D regions are grown in the active regions between the gate regions and this is followed by replacement metal gate (RMG) formation, shared gate metal fill (in the shared gate case), additional ILD deposition, middle-of-line (MOL)/BEOL formation and carrier wafer bonding. Next, the first and second layers of the first and second semiconductors are etched, followed by cap formation under the first and second gate regions and self-aligned STI etch to arrive at the initial semiconductor device assembly 501 of FIG. 5.

As shown in FIG. 5, the initial semiconductor device assembly 501 includes first gate structure 510 in a first active region, second gate structure 520 in a second active region, first gate support structure 530 underlying the first gate structure 510 and second gate support structure 540 underlying the second gate structure 520. The first gate structure 510 includes first nanosheets 511 surrounded by first metal gate material 512 and the second gate structure 520 includes second nanosheets 521 surrounded by second metal gate material 522. Isolation dielectric 550 and a shared gate plug 555 are interposed between the first and second metal gate materials 512 and 522. ILD 560 is disposed on the first and second metal gate materials 512 and 522, BEOL layer 565 is disposed on the ILD 560 and a carrier wafer 570 is disposed on the BEOL layer 565. A frontside contact 575 extends through the ILD 560 to electrically connect the BEOL layer 565 with the shared gate plug 555. The first gate support structure 530 includes a bottom dielectric layer 531, a pillar of silicon epitaxial material 532 and a cap 533. The bottom dielectric layer 531, the pillar of silicon epitaxial material 532 and the cap 533 are surrounded by a dielectric liner 534 and ILD material 535. The second gate support structure 540 includes a bottom dielectric layer 541, a pillar of silicon epitaxial material 542 and a cap 543. The bottom dielectric layer 541, the pillar of silicon epitaxial material 542 and the cap 543 are surrounded by a dielectric liner 544 and ILD material 545.

As shown in FIG. 6, a second semiconductor device assembly 601 is provided following removal of the caps 533 and 543 of FIG. 5 and removal of the isolation dielectric 550 of FIG. 5 executed with respect to the initial semiconductor device assembly 501 of FIG. 5. The second semiconductor device assembly 601 is thus characterized as having a first opening 610 between the first and second metal gate materials 512 and 522 and a second opening 620 between the first and second gate support structures 530 and 540.

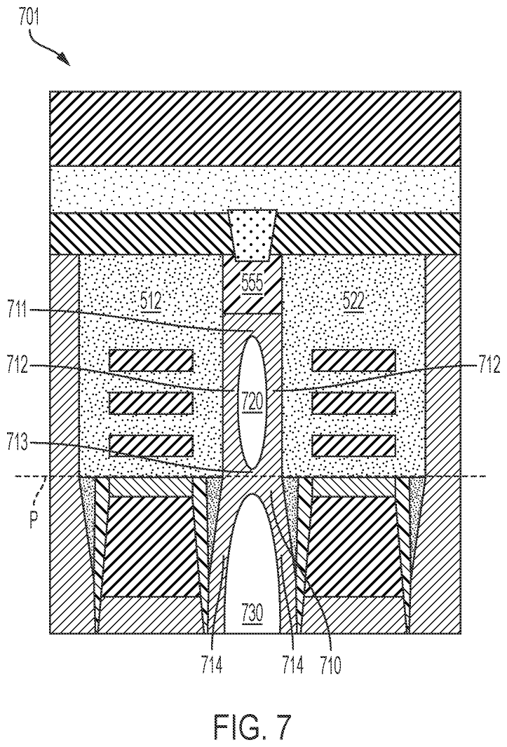

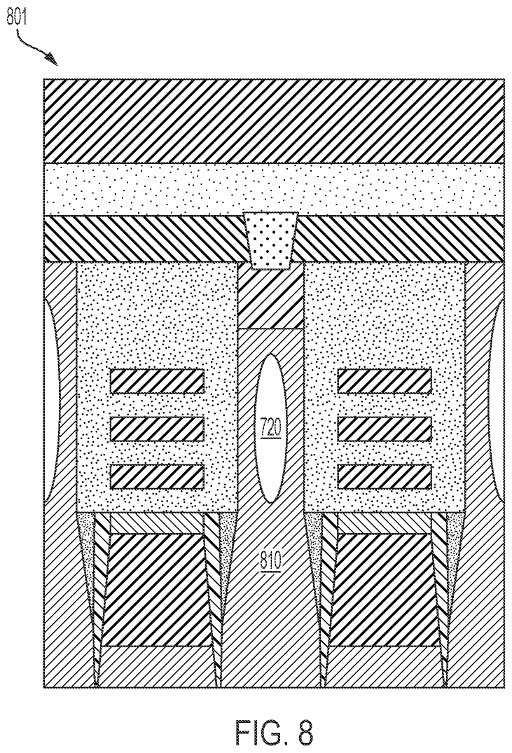

As shown in FIG. 7, a third semiconductor device assembly 701 is provided following an ALD operation executed with respect to the second semiconductor device assembly 601 of FIG. 6. The ALD operation results in an ALD dielectric fill that fills the first opening 610 and the second opening 620 of FIG. 6 with a first dielectric pillar 710. The ALD operation is isotropic and results in the first dielectric pillar 710 including upper pinched-off section 711, proximate to the shared gate plug 555 of FIG. 5 (or the ILD 560 of FIG. 5 in the non-shared gate case), first curved sidewalls 712 along the first and second metal gate materials 512 and 522, lower pinched-off section 713 proximate to a lowermost plane P of the first and second metal gate materials 512 and 513 and second curved sidewalls 714 along the first and second gate support structures 530 and 540. The ALD operation thus results in the first dielectric pillar 710 being formed to define a pinched-off air gap 720 between the first and second metal gate materials 512 and 513 and a partially pinched-off air gap 730 between the first and second gate support structures 530 and 540.

In accordance with embodiments, the first curved sidewalls 712 can have a width of about 20-33% (or about 2 nm) of a total width of the first opening 610.

As shown in FIG. 8, a fourth semiconductor device assembly 801 is provided following an additional ALD operation executed with respect to the third semiconductor device assembly 701 of FIG. 7. The additional ALD operation results in an ALD dielectric fill that fills the partially pinched-off air gap 730 of FIG. 7 with dielectric material and thus transforms the first dielectric pillar 710 of FIG. 7 into a backside dielectric pillar 810 formed to define the pinched-off airgap 720.

Following formation of the fourth semiconductor device assembly 801 of FIG. 8, the semiconductor device 101 of FIGS. 1, 2A and 2B (or the semiconductor device 101 of FIGS. 1, 3A and 3B) can be arrived at by multiple backside semiconductor manufacturing processes.

Various embodiments of the present disclosure are described herein with reference to the related drawings. Alternative embodiments can be devised without departing from the scope of this disclosure. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, can be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (rotated 90 degrees or at other orientations) and the spatially relative descriptors used herein interpreted accordingly.

The phrase “selective to,” such as, for example, “a first element selective to a second element,” means that the first element can be etched and the second element can act as an etch stop.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The term “conformal” (e.g., a conformal layer) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a {100} orientated crystalline surface can take on a {100} orientation. In some embodiments of the disclosure, epitaxial growth and/or deposition processes can be selective to forming on semiconductor surface, and cannot deposit material on exposed surfaces, such as silicon dioxide or silicon nitride surfaces.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present disclosure will now be provided. Although specific fabrication operations used in implementing one or more embodiments of the present disclosure can be individually known, the described combination of operations and/or resulting structures of the present disclosure are unique. Thus, the unique combination of the operations described in connection with the fabrication of a semiconductor device according to the present disclosure utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present disclosure. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present disclosure have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A semiconductor device, comprising:
first and second active regions;
a shared gate structure disposed across the first and second active regions and comprising first and second metal gate material in the first and second active regions, respectively;
a self-aligned backside dielectric pillar interposed between a first portion of the first metal gate material and a first portion of the second metal gate material; and
a shared gate plug interposed between a second portion of the first metal gate material and a second portion of the second metal gate material,
the self-aligned backside dielectric pillar defining a pinched-off air gap extending across a width-wise portion of the self-aligned backside dielectric pillar and along a height-wise portion of the self-aligned backside dielectric pillar.

2. The semiconductor device according to claim 1, wherein:
the shared gate structure comprises first and second gate structures in the first and second active regions,
the first gate structure comprising first nanosheets surrounded by the first metal gate material, and
the second gate structure comprising second nanosheets surrounded by the second metal gate material.

3. The semiconductor device according to claim 2, further comprising:
interlayer dielectric (ILD) extending across the first and second gate structures;
a back-end-of-line (BEOL) layer disposed on the ILD;
a frontside contact extending through the ILD and being electrically connected to the shared gate plug and the BEOL layer; and
a carrier layer disposed on the BEOL layer.

4. The semiconductor device according to claim 2, further comprising a backside power rail (BPR) and a backside contact electrically connected to the BPR.

5. The semiconductor device according to claim 1, wherein the pinched-off air gap is ovular and elongate height-wise.

6. The semiconductor device according to claim 1, wherein the self-aligned backside dielectric pillar comprises:
an upper pinched-off section delimiting an upper extent of the pinched-off air gap and proximate to the shared gate plug; and
a lower pinched-off section delimiting a lower extent of the pinched-off air gap and proximate to a lowermost plane of the first and second metal gate materials in the first and second active regions, respectively.

7. The semiconductor device according to claim 1, wherein:
side sections of the self-aligned backside dielectric pillar have a minimum width corresponding to a maximum width of the pinched-off air gap, and
respective widths of the side sections are up to about 20-33% of a total width of the backside dielectric pillar.

8. A semiconductor device, comprising:
first and second active regions;
a non-shared gate structure disposed across the first and second active regions and comprising first and second metal gate material in the first and second active regions, respectively; and
a self-aligned backside dielectric pillar interposed between the first metal gate material and the second metal gate material,
the backside dielectric pillar defining a pinched-off air gap extending across a width-wise portion of the self-aligned backside dielectric pillar and along a height-wise portion of the self-aligned backside dielectric pillar.

9. The semiconductor device according to claim 8, wherein:
the non-shared gate structure comprises first and second gate structures in the first and second active regions,
the first gate structure comprising first nanosheets surrounded by the first metal gate material, and
the second gate structure comprising second nanosheets surrounded by the second metal gate material.

10. The semiconductor device according to claim 9, further comprising:
interlayer dielectric (ILD) extending across the first and second gate structures;
a back-end-of-line (BEOL) layer disposed on the ILD; and
a carrier layer disposed on the BEOL layer.

11. The semiconductor device according to claim 9, further comprising a backside power rail (BPR) and a backside contact electrically connected to the BPR.

12. The semiconductor device according to claim 8, wherein the pinched-off air gap is ovular and elongate height-wise.

13. The semiconductor device according to claim 8, wherein the self-aligned backside dielectric pillar comprises:
an upper pinched-off section delimiting an upper extent of the pinched-off air gap and proximate an uppermost plane of the first and second metal gate materials in the first and second active regions, respectively; and
a lower pinched-off section delimiting a lower extent of the pinched-off air gap and proximate to a lowermost plane of the first and second metal gate materials in the first and second active regions, respectively.

14. The semiconductor device according to claim 8, wherein:
side sections of the self-aligned backside dielectric pillar have a minimum width corresponding to a maximum width of the pinched-off air gap, and
respective widths of the side sections are up to about 20-33% of a total width of the backside dielectric pillar.

15. A semiconductor device fabrication method, comprising:
forming a gate structure across first and second active regions and comprising first and second metal gate material in the first and second active regions, respectively, and first and second support structures underlying the first and second metal gate material, respectively;
removing material from between the first and second metal gate material and from between the first and second support structures to form first and second openings, respectively;
executing atomic layer deposition (ALD) to partially fill the first opening with dielectric defining a pinched-off air gap therein and to partially fill the second opening with the dielectric defining a partially pinched-off air gap therein; and
executing additional ALD to completely fill the partially pinched-off air gap with the dielectric whereby the dielectric forms a self-aligned backside dielectric pillar.

16. The semiconductor device fabrication method according to claim 15, wherein the gate structure is one of a shared gate structure and a non-shared gate structure.

17. The semiconductor device fabrication method according to claim 15, wherein the pinched-off air gap is ovular and elongate height-wise.

18. The semiconductor device fabrication method according to claim 15, wherein the executing of the ALD comprises:
executing the ALD to form an upper pinched-off section delimiting an upper extent of the pinched-off air gap and proximate an uppermost plane of the first and second gate metal materials in the first and second active regions, respectively; and
executing the ALD to form a lower pinched-off section delimiting a lower extent of the pinched-off air gap and proximate to a lowermost plane of the first and second gate metal materials in the first and second active regions, respectively.

19. The semiconductor device fabrication method according to claim 15, wherein:
the executing of the ALD comprises executing the ALD such that side sections of the self-aligned backside dielectric pillar have a minimum width corresponding to a maximum width of the pinched-off air gap, and
the executing of the ALD comprises executing the ALD such that respective widths of the side sections are up to about 20-33% of a total width of the backside dielectric pillar.

20. The semiconductor device fabrication method according to claim 15, further comprising:
completing complementary-metal-oxide-semiconductor (CMOS) operations; and
completing backside power rail (BPR) formations.
